(19) United States
(12) Patent Application Publication
(10) Pub. No.: US 2015/0348925 A1
(43) Pub. Date: Dec. 3, 2015

(54) REDUCED TITANIUM UNDERCUT IN ETCH PROCESS

(71) Applicant: APPLIED Materials, Inc., Santa Clara, CA (US)

(72) Inventors: David P. Surdock, Kalispell, MT (US); Marvin L. Bernt, Kalispell, MT (US)

(73) Assignee: APPLIED MATERIALS, INC., Santa Clara, CA (US)

(21) Appl. No.: 14/725,242

(22) Filed: May 29, 2015

Related U.S. Application Data
(60) Provisional application No. 62/004,751, filed on May 29, 2014.

(51) Int. Cl. H01L 23/00

(52) U.S. Cl. CPC H01L 24/13; H01L 24/11; H01L 2224/11013; H01L 2224/11005; H01L 2224/11462; H01L 2224/11831; H01L 2224/13666; H01L 2224/1357; H01L 2224/13563; H01L 2224/13084; H01L 2224/13027; H01L 2224/13018; H01L 2224/13006

(57) ABSTRACT

In accordance with one embodiment of the present disclosure, a method of forming a metal feature includes etching a portion of a first metal layer using a first etching chemistry, and etching a portion of a barrier layer using a second etching chemistry to achieve a barrier layer undercut of less than or equal to 2 times the thickness of the barrier layer.

### CROSS-REFERENCE TO RELATED APPLICATION

This application claims the benefit of U.S. Provisional Application No. 62/004,751, filed May 29, 2014, the disclosure of which is hereby expressly incorporated by reference herein in their entirety.

### BACKGROUND

In wafer level packaging applications, a thin refractory metal layer is disposed on a substrate to act as a diffusion barrier and to improve the adhesion between noble metals like copper, gold, and silver to substrates like silicon, silicon dioxide, glass, and ceramics. Typically, the barrier is a thin titanium or titanium-compound layer. A seed layer is deposited on the barrier layer, then photoresist is patterned on the seed layer to provide a recess for feature formation.

After metal layers have been deposited in the recess for feature formation, the photoresist is removed (see FIG. 3). Patterning of the underlying barrier and seed layers for feature formation is usually performed by wet chemical etching. When etching the barrier layer, the etching rates of the lateral etch as compared to the vertical etch can be different in a particular etching chemistry. Such differences can be enhanced by a galvanic etching effect. Hence, the etching process step can result in an unfavorable undercut in the barrier layer (for example, see the undercut in titanium layer 122 in FIG. 15).

Therefore, there exists a need for improved methods for forming metal features to decrease titanium undercut in the etch process. Embodiments of the present disclosure are directed to these and other improvements.

### SUMMARY

This summary is provided to introduce a selection of concepts in a simplified form that are further described below in the Detailed Description. This summary is not intended to identify key features of the claimed subject matter, nor is the summary intended to be used as an aid in determining the scope of the claimed subject matter.

In accordance with one embodiment of the present disclosure, a method of forming a metal feature is provided. The method includes providing a microfeature workpiece that includes a substrate, a continuous titanium-containing barrier layer disposed on the substrate, a continuous first metal layer disposed on the barrier layer having a thickness, and a dielectric layer patterned on the first metal layer to provide a recess defining sidewall surfaces and a bottom surface, wherein the bottom surface of the recess is a metal surface and the sidewall surfaces of the recess are dielectric surfaces. The method further includes depositing a second metal layer within the recess on an exposed top surface of the first metal layer; removing the dielectric layer to provide an exposed feature; etching a portion of the first metal layer using a first etching chemistry; and etching a portion of the barrier layer using a second etching chemistry to achieve a barrier layer undercut of less than or equal to 2 times the thickness of the barrier layer.

In accordance with another embodiment of the present disclosure, a method of forming a metal feature is provided. The method includes providing a microfeature workpiece that includes a substrate, a continuous titanium-containing barrier layer disposed on the substrate, a continuous metal seed layer disposed on the barrier layer, and a dielectric layer patterned on the metal seed layer to provide a recess defining sidewall surfaces and a bottom surface, wherein the bottom surface of the recess is a metal surface and the sidewall surfaces of the recess are dielectric surfaces. The method further includes electrochemically depositing a first metal layer within the recess on an exposed top surface of the metal seed layer; removing the dielectric layer to provide an exposed feature; etching a portion of the first metal layer using a first etching chemistry; and

etching a portion of the barrier layer using a second etching chemistry including hydrogen peroxide and a fluoride ion.

In accordance with another embodiment of the present disclosure, a microfeature workpiece is provided. The workpiece includes a substrate and a microfeature disposed on the substrate, the microfeature including a titanium-containing barrier layer above the substrate, a metal seed layer above the barrier layer, and at least a first metallization layer disposed on the metal seed layer, wherein the barrier layer has an undercut of less than 2 times the thickness of the barrier layer.

In accordance with any of the embodiments described herein, the first metal layer may be a seed layer.

In accordance with any of the embodiments described herein, a method may further include electrochemically depositing a third metal layer within the recessed feature on an exposed top surface of the second metal layer.

In accordance with any of the embodiments described herein, a method may further include electrochemically depositing a fourth metal layer within the recessed feature on an exposed top surface of the third seed layer.

In accordance with any of the embodiments described herein, the etching chemistry may include hydrogen peroxide and a fluoride ion.

In accordance with any of the embodiments described herein, the etching chemistry may include hydrogen peroxide and ammonium fluoride.

In accordance with any of the embodiments described herein, the molarity of the hydrogen peroxide in the etching chemistry may be in the range of 0.300 M to 17.600 M.

In accordance with any of the embodiments described herein, the molarity of the ammonium fluoride in the etching chemistry may be in the range of 0.012 M to 0.900 M.

In accordance with any of the embodiments described herein, the molar ratio between hydrogen peroxide and ammonium fluoride may be in the range of 83:1 to 13:1.

In accordance with any of the embodiments described herein, the etching chemistry may further include a caustic solution.

In accordance with any of the embodiments described herein, the etching chemistry may further include ammonium hydroxide.

In accordance with any of the embodiments described herein, the temperature of the etching chemistry may be in the range of 35 degrees C. to 80 degrees C.

In accordance with any of the embodiments described herein, the pH of the etching chemistry may be in the range of about 4.5 to about 8.0.

### DESCRIPTION OF THE DRAWINGS

The foregoing aspects and many of the attendant advantages of the present disclosure will become more readily appreciated by reference to the following detailed description, when taken in conjunction with the accompanying drawings, wherein:

FIGS. 1-5 are a series of schematic diagrams directed to a method of forming a metal feature in accordance with one embodiment of the present disclosure;

FIGS. 6-13 are graphical representations of experimental results for various processing conditions; and

FIGS. 14 and 15 are a series of schematic diagrams directed to a method of forming a metal feature in accordance with a previously designed process.

### DETAILED DESCRIPTION

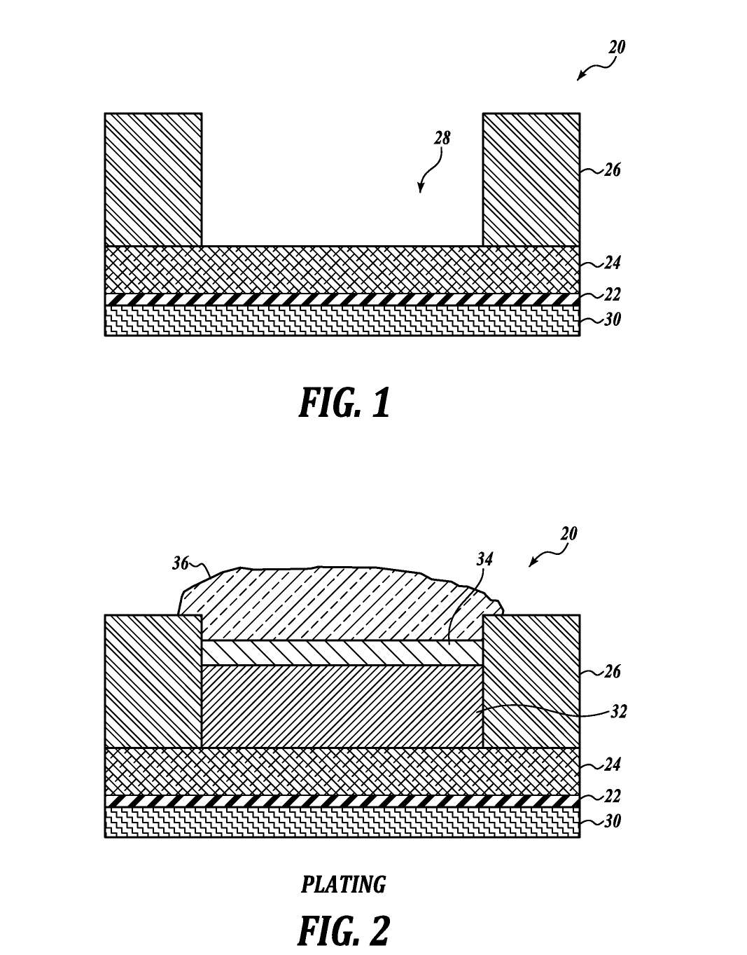

Embodiments of the present disclosure are generally directed to methods of forming metal features, particularly in wafer level packaging applications. A method in accordance with one embodiment of the present disclosure is provided in the series of schematic diagrams of FIGS. 1-5. The method includes etching a portion of the barrier layer using an etching chemistry to achieve reduced undercut as compared to methods using previously developed wet etching chemistry.

As used herein, the terms “microfeature workpiece” or “workpiece” refer to substrates on and/or in which micro devices are formed. Such substrates include semiconductive substrates (e.g., silicon wafers and gallium arsenide wafers), nonconductive substrates (e.g., ceramic or glass substrates), and conductive substrates (e.g., doped wafers). Examples of micro devices include microelectronic circuits or components, micromechanical devices, microelectromechanical devices, micro optics, thin film recording heads, data storage elements, microfluidic devices, and other small scale devices.

As used herein, the term “substrate” refers to a base layer of material over which one or more metallization levels is disposed. The substrate may be, for example, a semiconductor, a ceramic, a dielectric, etc.

The schematic diagrams provided herein in FIGS. 1-5, 14, and 15 are representative only and are not drawn to scale for the methods of forming metal features described herein, particularly in wafer level packaging applications.

The formation of metal alloy features in accordance with processes described herein can be carried out in a tool designed to electrochemically deposit metals such as one available from Applied Materials, Inc., under the trademark Raider™. An integrated tool can be provided to carry out a number of process steps involved in the formation of microfeatures on microfeature workpieces.

The method illustrated in FIGS. 1-5 is a method of forming a metal feature in an exemplary wafer level packaging application. Exemplary wafer level packaging applications may include, but are not limited to bond pads, bumps, pillars, redistribution layers (RDLs), and post-TSV bumping. The technology of the present disclosure may also be used in other technology applications, for example, patterned etching using a photomask, instead of plating into a feature.

Referring to FIGS. 1-5, a method of forming a metal feature 20 will now be described. As can be seen in FIG. 1, a barrier (or adhesion) layer 22 is disposed on a substrate 30. The substrate 30 may be a silicon, silicon dioxide, glass, or ceramic substrate. The barrier layer 22 may be designed to prevent diffusion of a metal, such as copper, into the substrate 30, or to improve the adhesion between noble metals for metallization, such as copper, gold, and silver to the substrate. Typically, the barrier layer 22 is a thin titanium or titanium-compound barrier layer, such as a titanium nitride or titanium tungsten.

Still referring to FIG. 1, a first metal layer 24 is deposited on the barrier layer 22. The first metal layer 24 may be a seed layer. In one non-limiting example, the seed layer may be a copper seed layer. As another non-limiting example, the seed layer may be a copper alloy seed layer, such as copper manganese, copper cobalt, or copper nickel alloys. In the case of depositing copper in a feature, there are several exemplary options for the seed layer. For example, the seed layer may be a PVD copper seed layer. The seed layer may also be formed by using other deposition techniques, such as CVD or ALD.

Still referring to FIG. 1, a dielectric layer, such as a photoresist 26 layer, is patterned on the first metal layer 24 to provide a recess 28 for feature formation within the photoresist 26. Photoresist 26 can be patterned using conventional techniques such as photolithography.

Referring to FIG. 2, metallization layers 32, 34, and 36 are formed in the recess 28. In one exemplary embodiment of the present disclosure, the subsequent metallization layers deposited in the recess may include one or more layers. In the illustrated embodiment, the metallization includes three layers, which may be a copper layer 32, a nickel layer 34, and a tin-silver cap layer 36. The metallization layers may be formed within recess using conventional techniques such as electrolytic, electroless, PVD, or CVD techniques.

Although the exemplary embodiment is directed to a typical copper pillar packaging application including a copper layer 32, a nickel layer 34, and a tin-silver cap layer 36, other subsequent metallization layers are also within the scope of the present disclosure. As non-limiting examples, a suitable RDL application metallization may include a copper layer, followed by a nickel layer, followed by a gold layer. In an exemplary copper pillar application, metallization may include a copper layer, followed by a nickel layer, followed by a tin-silver layer. In an exemplary bump application, metallization may include a copper layer, a nickel layer, and either a lead-tin layer or a tin-silver layer. In an exemplary bond pad application, metallization may include a copper layer, followed by a nickel layer, followed by a gold, palladium, or indium layer.

In typical wafer level packaging features, feature size can be in the range of about 2 microns up to about 100 microns in diameter.

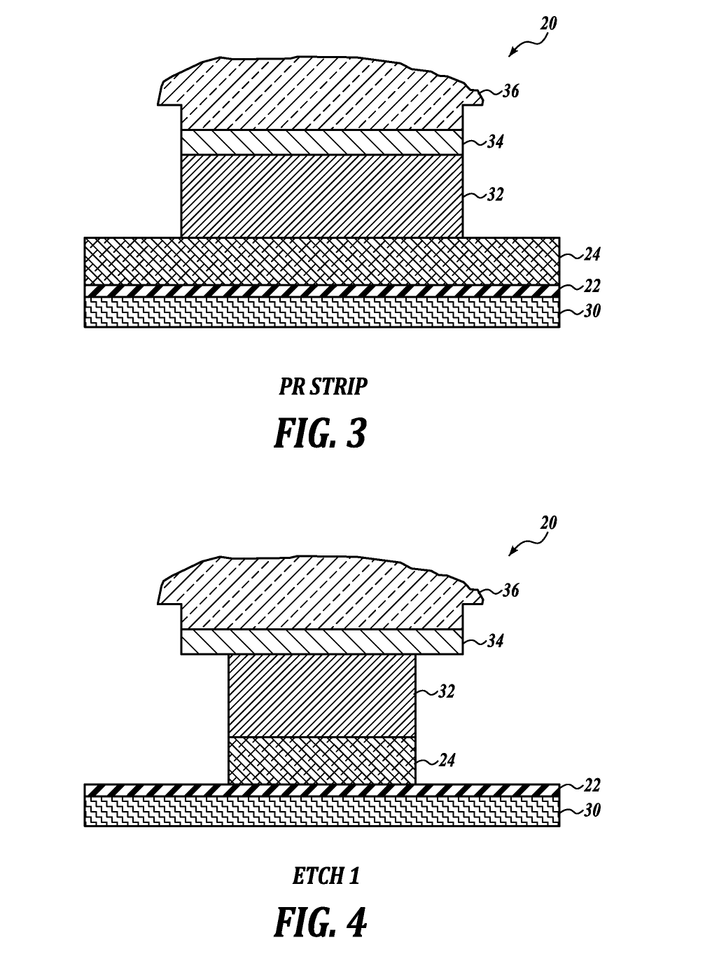

Referring to FIG. 3, after one or more metal layers 32, 34, and 36 have been deposited in the recess 28 for feature formation, the photoresist 26 is removed.

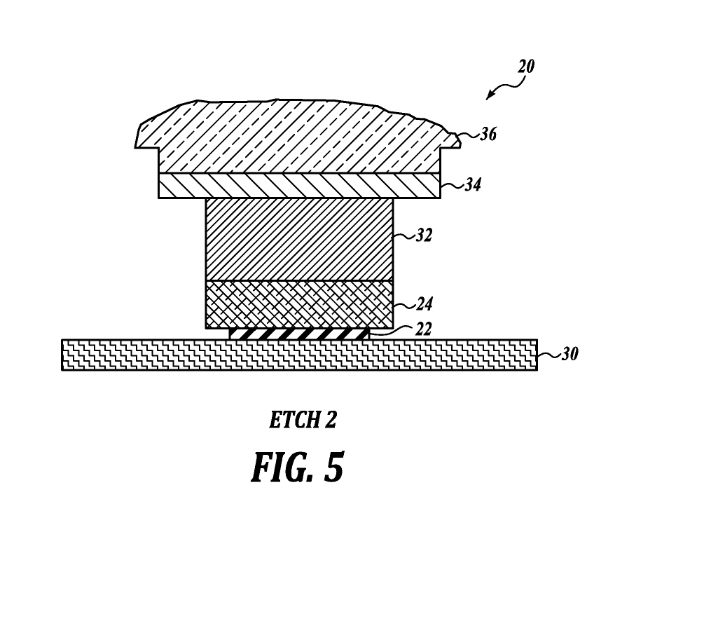

Referring to FIGS. 4 and 5, after the photoresist 26 has been removed, patterning of the underlying barrier layer 22 and first metal layer 24 can be performed by a wet chemical etching process called under-bump metallization (UBM) etching. In the illustrated embodiment of FIGS. 1-5, the etching process is a two-step etch. First, referring to FIG. 4, the first metal layer 24, for example, a copper seed layer is etched using an etching solution known in the art. During this etching process, metallization layer 32 may also be subjected to an etch.

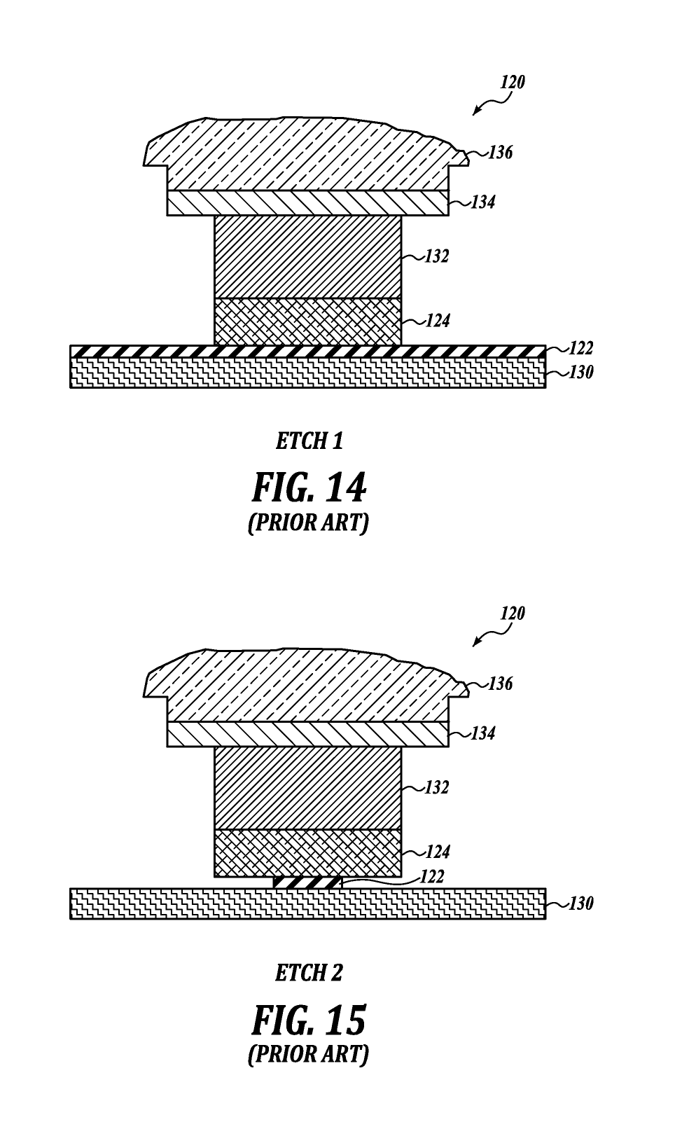

Second, referring to FIG. 5, barrier layer 22 is etched in accordance with methods described herein. When etching the barrier layer using previously developed processes, the etching rates of the lateral etch as compared to the vertical etch can be different in a particular etching chemistry. For example, referring to FIGS. 14 and 15, processes using previously designed wet etching chemistry for UBM etching of the barrier layer 122 undercut a significant portion of the titanium barrier metal layer 122. As one example, a previously designed wet etching is a buffered oxide etch (BOE) that used buffered hydrogen fluoride (HF or BHF). Not only does HF increase the titanium undercut, but HF is a hazardous material requiring special handling.

As seen in FIG. 4, a copper etch is typically isotropic, meaning that the copper seed layer typically etches at substantially the same rate laterally as vertically toward the substrate. In contrast, a titanium barrier layer tends to etch more laterally than vertically, as compared to the copper seed layer etch because of the presence of titanium oxide in the open area. An HF etchant solution further promotes a galvanic etching phenomenon, such that the etching rate of the titanium barrier layer is enhanced in the lateral etch as compared to the vertical etch.

In some applications using the previously developed methods, the barrier layer etch may be undercut by about 5 to 10 times the thickness of the barrier layer. With decreasing feature size in the semiconductor industry, a significant undercut of the barrier layer during the wet etching process can result in unstable features on the wafer because of reduced adhesion area of the barrier layer to the substrate. Reduced adhesion area may result in the bump lifting away or breaking away from the substrate. See, for example, the undercut in titanium layer 122 using an HF etching solution in FIG. 15.

In accordance with some embodiments of the present disclosure, the etching chemistry has a composition that reduces the titanium layer undercut seen in previously designed methods. In that regard, the etching chemistry has titanium layer undercut in the range of about 0 to 2 times the thickness of the barrier layer. In many applications, a lateral to vertical etch ratio of 1 to 1 is advantageous. Therefore, an etch ratio of 0 to 1, which may be achieved by methods disclosed herein, is particularly advantageous.

Etching chemistry in accordance with some embodiments of the present disclosure includes hydrogen peroxide and ammonium fluoride. As a non-limiting example, the volumetric ratio between 9.79 M hydrogen peroxide and 11.987 M ammonium fluoride in the etchant solution may be in the range of about 100:1 to about 100:6. (Molar ratio about 83:1 to about 13:1.)

In addition to ammonium fluoride, other fluoride ions are within the scope of the present disclosure. As non-limiting examples, other fluoride containing compounds include, but are not limited to, fluoride salts, such as calcium fluoride (CaF), sodium fluoride (NaF), and other suitable fluoride compounds. Use of ammonium fluoride may have advantages in semiconductor manufacture compared to other fluoride salt compounds to avoid potential negative implications of calcium or other unwanted cations that may deposit in the metal feature.

In one embodiment of the present disclosure, hydrogen peroxide molarity in the etching solution is in the range of 0.300 M to 17.600 M. In another embodiment of the present disclosure, hydrogen peroxide molarity is in the range of 1.600 M to 9.800 M. In another embodiment of the present disclosure, hydrogen peroxide molarity is in the range of 4.700 M to 9.600 M.

In one embodiment of the present disclosure, ammonium fluoride molarity in the etching solution is in the range of 0.012 M to 0.900 M. In another embodiment of the present disclosure, ammonium fluoride molarity is in the range of 0.110 M to 0.700 M. In another embodiment of the present disclosure, ammonium fluoride molarity is in the range of 0.200 M to 0.500 M.

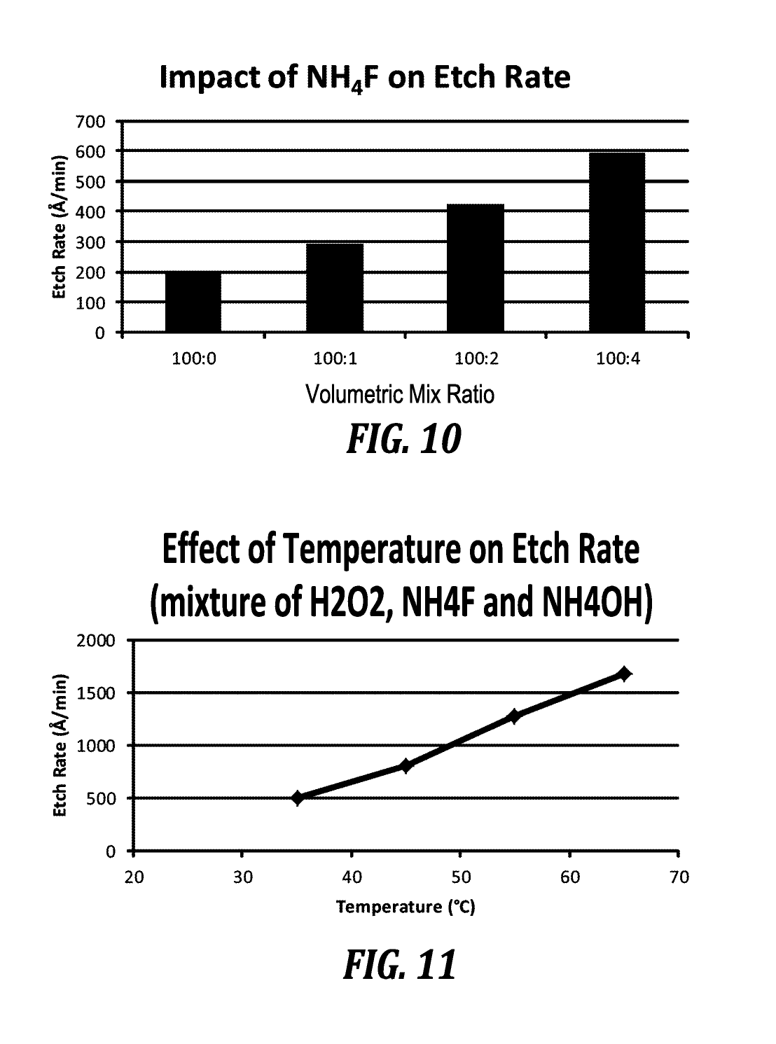

Experimental testing shows that hydrogen peroxide by itself will etch the seed layer and barrier layer, but at a reduced etch rate compared to an etching solution containing hydrogen peroxide and ammonium fluoride. As can be seen in FIG. 10, an etching solution of only hydrogen peroxide etches at a rate of about 200 A/min as compared to an etch rate of almost 600 A/min for an etching solution containing 9.79 M hydrogen peroxide combined with 11.987 M ammonium fluoride in a volumetric ratio of 100:4. Experimental results also show that increasing the amount of ammonium fluoride in the etching solution from a volumetric ratio of 100:1 to a volumetric ratio of 100:4, increases the etching rate, as described below in EXAMPLE 5 and FIG. 10.

Experimental testing shows that ammonium fluoride alone will not effectively etch the barrier layer.

In one embodiment of the present disclosure, a suitable temperature range for the etching solution is in the range of about 20 to about 80 degrees C. In another embodiment of the present disclosure, a suitable temperature range for the etching solution is in the range of about 35 to about 65 degrees C. In another embodiment of the present disclosure, a suitable temperature range for the etching solution is in the range of about 55 to about 65 degrees C. Experimental testing shown that increasing temperature can increase etching rate, as described below in EXAMPLE 6 and FIG. 11. However, increasing temperature can also have the negative drawback of causing hydrogen peroxide in the chemistry to break down, which tends to affect bath life.

In one embodiment of the present disclosure, a suitable pH range for the etching chemistry is less than about 8. In another embodiment of the present disclosure, a suitable pH range for the etching chemistry is in the range of about 4.5 to about 8. In another embodiment of the present disclosure, a suitable pH range for the etching chemistry is in the range of about 6 to about 7. The inventors have found that increasing pH increased the etch rate of the etching solution, as can be seen in the experimental results shown in FIG. 7 and described in EXAMPLE 2 below.

A suitable caustic may be added to adjust the pH of the chemistry, such as ammonium hydroxide or sodium hydroxide. However, the inventors have observed that a pH above 8.0 tends to cause hydrogen peroxide in the chemistry to break down, which tends to affect bath life. In one embodiment of the present disclosure, ammonium hydroxide may be added to the etchant solution in a molarity of 0 to 0.550 M. In another embodiment of the present disclosure, ammonium hydroxide may be added to the etchant solution in a molarity of 0 to 0.300 M. In another embodiment of the present disclosure, ammonium hydroxide may be added to the etchant solution in a molarity of 0.035 M to 0.150 M.

One advantageous effect of the chemistries described in the present disclosure including hydrogen peroxide, a fluoride ion in solution, and a caustic agent, is that the chemistries tend to have a synergistic etch rate effect. As can be seen in FIG. 10, an etching solution of only hydrogen peroxide etches at a rate of about 200 A/min as compared to an etch rate of almost 600 A/min for an etching solution containing 9.79 M hydrogen peroxide combined with 11.987 M ammonium fluoride in a volumetric ratio of 100:4. As can be seen in FIG. 7, the addition of NH4OH increases the etch rate to more than 1200 A/min at 55 degrees C. and to more than 1600 A/min at 65 degrees C.

In another embodiment of the present disclosure, another caustic such as sodium hydroxide may be added to the etchant solution instead of ammonium hydroxide in a molarity of 0 to 0.750 M. In another embodiment of the present disclosure, sodium hydroxide may be added to the etchant solution in a molarity of 0 to 0.300 M. In another embodiment of the present disclosure, sodium hydroxide may be added to the etchant solution in a molarity of 0.400 M to 0.180 M. Sodium hydroxide or other caustics may not be selected caustics for semiconductor manufacture because of potential negative implications of sodium or other unwanted cations depositing in the metal feature.

The following EXAMPLES provide experimental results for chemistry composition, temperature of etchant, pH of etchant, and use of different caustic agents.

### Example 1

### Impact of Etchant on TI Undercut for 1000 A Layer

Comparative etching chemistries: (1) HF (“dHF”); (2) hydrogen peroxide and ammonium fluoride (“AMAT TiV1”); and (3) hydrogen peroxide, ammonium fluoride, and ammonium hydroxide (“AMAT TiV2”). Respective titanium barrier layer undercut values are provided for a 50 micron feature, a 20 micron sparse feature, and a 20 micron dense feature, as provided in the table below.

| Etchant | dHF | H₂O₂ + NH₄F | H₂O₂ + NH₄F + NH4OH |
|---|---|---|---|
| 50 μm Feature | 0.489 | 0.131 | 0.099 |
| 20 μm Sparse | 0.78 | 0.219 | 0.212 |
| Feature | | | |
| 20 μm Dense | 0.971 | 0.191 | 0.105 |
| Feature | | | |

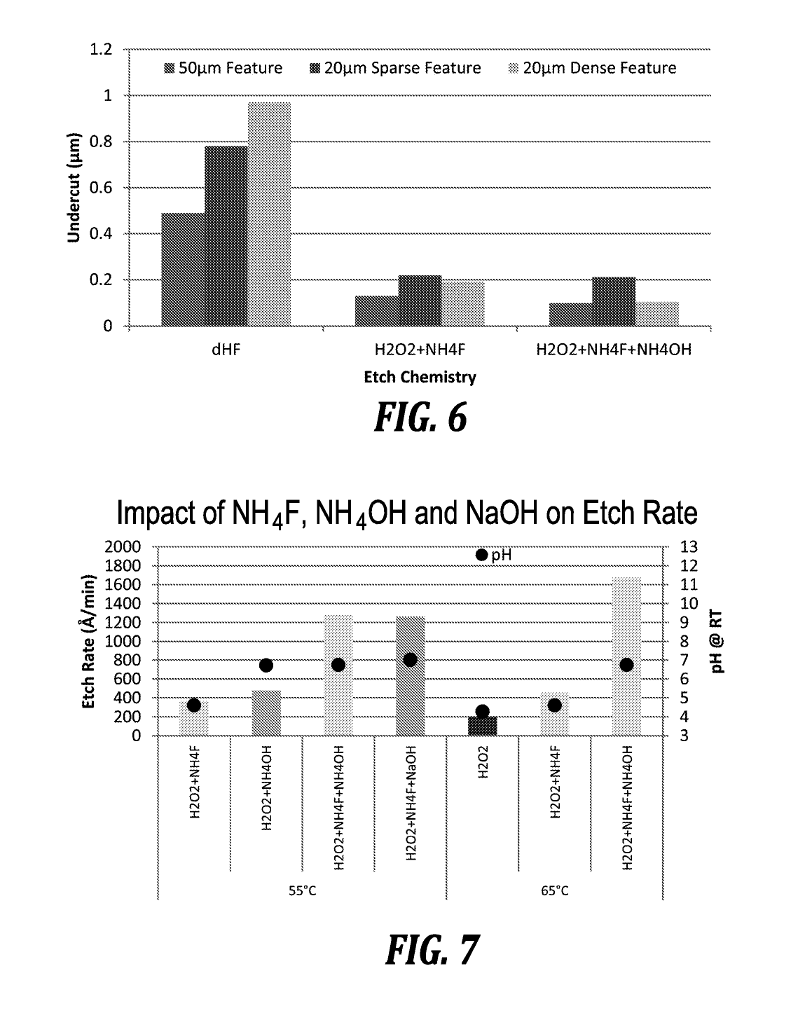

The experimental results are graphically represented in FIG. 6. This example shows that substantially similar undercut results are achieved with etching chemistries including hydrogen peroxide and ammonium fluoride, and one of the two including ammonium hydroxide for pH increase. The effect of pH increase is described below in EXAMPLE 2.

### Example 2

### Impact of NH4OH on Etch Rate

In an etching chemistry including only hydrogen peroxide and ammonium fluoride, an etch rate of 364 A/min was achieved at 55 degrees C. and pH 4.6. Comparatively, in an etching chemistry including hydrogen peroxide and ammonium hydroxide, an etch rate of 479 A/min was achieved at 55 degrees C. and pH 6.72. Comparatively, in an etching chemistry including hydrogen peroxide, ammonium fluoride, and ammonium hydroxide, an etch rate of 1280 A/min was achieved at 55 degrees C. and pH 6.74. Comparatively, in an etching chemistry including hydrogen peroxide, ammonium fluoride, and sodium hydroxide, an etch rate of 1265 A/min was achieved at 55 degrees C. and pH 7.01.

In an etching chemistry including only hydrogen peroxide and ammonium fluoride, an etch rate of 457 A/min was achieved at 65 degrees C. and pH 4.6. Comparatively, in an etching chemistry including hydrogen peroxide, ammonium fluoride, and ammonium hydroxide, an etch rate of 1675 A/min was achieved at 65 degrees C. and pH 6.74. Comparatively, in an etching chemistry including only hydrogen peroxide, an etch rate of 202 A/min was achieved at 65 degrees C. and pH 4.28.

The experimental results are graphically represented in FIG. 7. This example shows that the addition of a caustic, such as ammonium hydroxide or sodium hydroxide, substantially increases the etch rate. Moreover, a temperature increase from 55 degrees C. to 65 degrees C. increases etch rate. In addition, the combination of hydrogen peroxide, ammonium fluoride, and a caustic (ammonium hydroxide or sodium hydroxide), increases etch rate (to 1280 A/min at 55 degrees C.) more than the combined etch rates of (1) hydrogen peroxide and ammonium fluoride (364 A/min at 55 degrees C.) and (2) hydrogen peroxide and ammonium hydroxide (479 A/min at 55 degrees C.).

The impact of NH4OH and NAOH on the pH of the etching solution is described below in EXAMPLES 3 and 4.

### Example 3

### Impact of NH4OH on pH of Solution

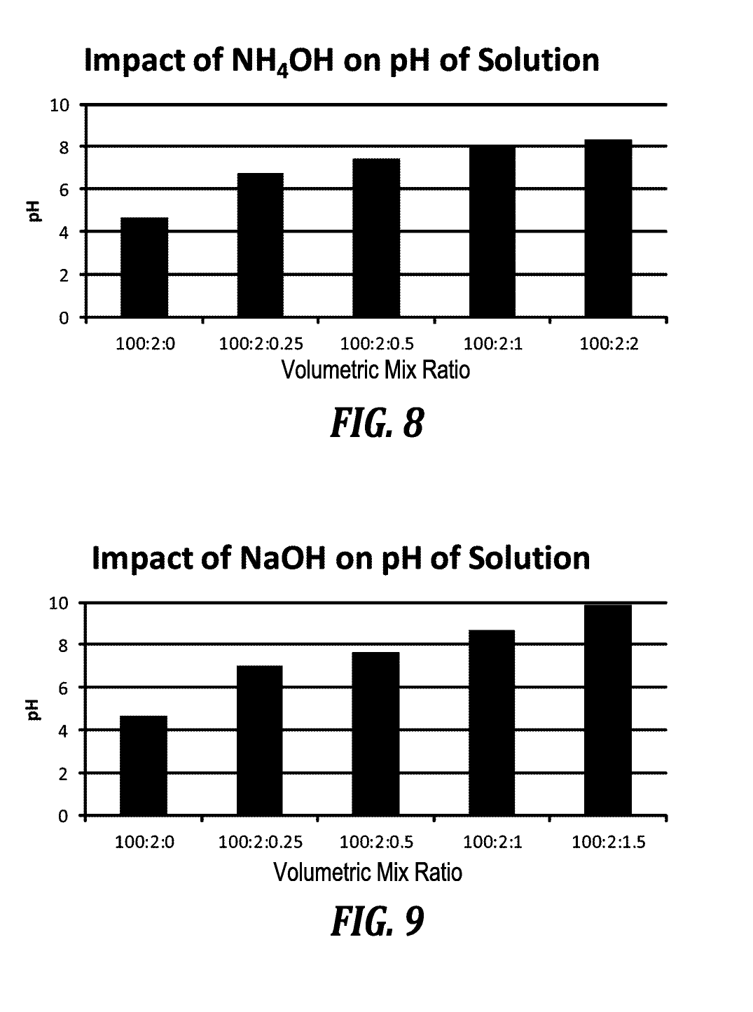

pH was monitored for various hydrogen peroxide (H2O2), ammonium fluoride (NH4F), and ammonium hydroxide (NH4OH) mix ratios. The molarity of the hydrogen peroxide was set at 9.79 M. The molarity of the ammonium fluoride was set at 11.987 M. The molarity of the ammonium hydroxide was set at 14.5 M. The ratio of hydrogen peroxide to ammonium fluoride was set at 100:2. As the ratio of ammonium hydroxide increased from 0 part per 100 to 1.5 parts per 100, pH increased from 4.65 to 8.37. The experimental results are graphically represented in FIG. 8. Excessive breakdown of hydrogen peroxide was observed at pH greater than 8.0.

### Example 4

### Impact of NaOH on pH of Solution

pH was monitored for various hydrogen peroxide (H2O2), ammonium fluoride (NH4F), and sodium hydroxide (NaOH) mix ratios. The molarity of the hydrogen peroxide was set at 9.79 M. The molarity of the ammonium fluoride was set at 11.987 M. The molarity of the sodium hydroxide was set at 19.4 M. The ratio of hydrogen peroxide to ammonium fluoride was set at 100:2. As the ratio of sodium hydroxide increased from 0 part per 100 to 1.5 parts per 100, pH increased from 4.65 to 9.86. The experimental results are graphically represented in FIG. 9. Excessive breakdown of hydrogen peroxide was observed at pH greater than 8.0.

### Example 5

### Impact of NH4F on Etch Rate

Etch rate was monitored for various hydrogen peroxide (H2O2) and ammonium fluoride (NH4F) mix ratios. The molarity of the hydrogen peroxide was set at 9.79 M. The molarity of the ammonium fluoride was set at 11.987 M. As the ratio of ammonium fluoride increased from 1 part per 100 to 4 parts per 100, the etch rate increase from 294.8 A/min to 591.6 A/min. With no ammonium fluoride, the etch rate was at 202 A/min. The experimental results are graphically represented in FIG. 10.

### Example 6

### Impact of Temperature on Etch Rate

For a particular etching chemistry including hydrogen peroxide (H2O2) and ammonium fluoride (NH4F), increasing temperature increased etch rate. An etch rate of about 500 A/min was achieved at 35 degrees C. Comparatively, an etch rate increase of nearly four times of 1675 A/min was achieved at 65 degrees C. The experimental results are graphically represented in FIG. 11.

### Example 7

### Impact of NH4F on pH of H2O2

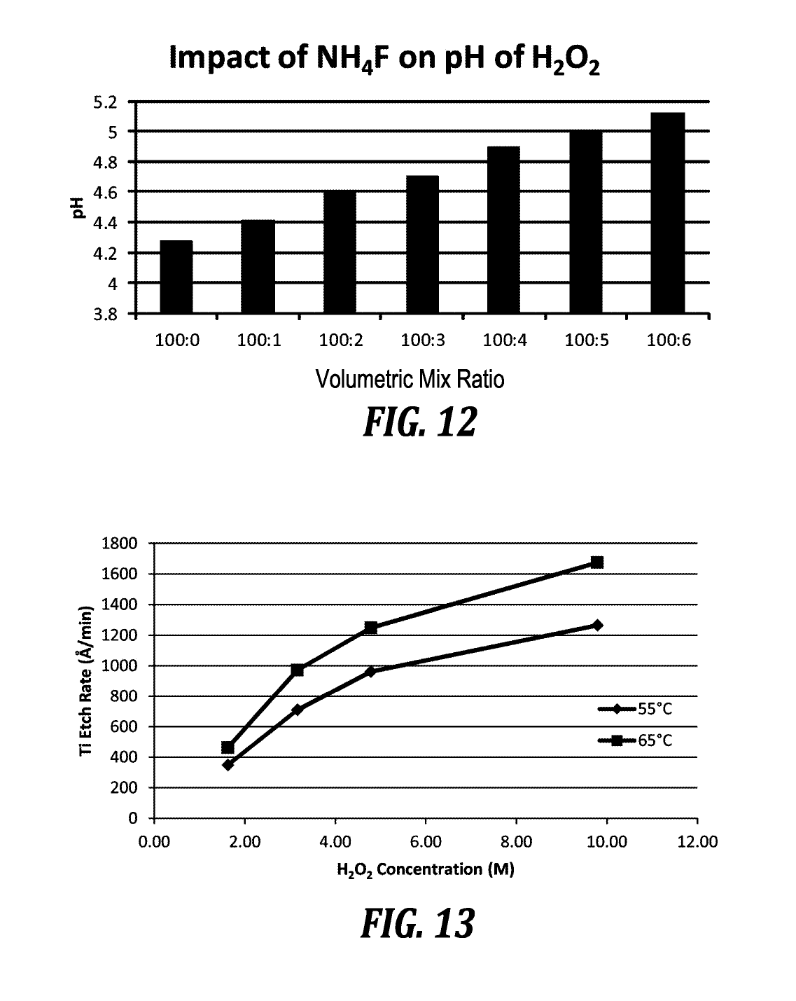

pH was monitored for various hydrogen peroxide (H2O2) and ammonium fluoride (NH4F) mix ratios. The molarity of the hydrogen peroxide was set at 9.79 M. The molarity of the ammonium fluoride was set at 11.987 M. As the ratio of ammonium fluoride increased from 0 part per 100 to 6 parts per 100, pH increased from 4.28 to 5.12. The experimental results are graphically represented in FIG. 12. This example shows that NH4F molarity has little impact on the pH of the etching chemistry.

### Example 8

### Impact of H2O2 Concentration on Etch Rate

For a particular etching chemistry including hydrogen peroxide (H2O2), ammonium fluoride (NH4F), and ammonium hydroxide (NH4OH), increasing hydrogen peroxide concentration and temperature increased etch rate. An etch rate of 349 A/min was achieved at 55 degrees C. and with an H2O2 concentration of 1.63 M. Comparatively, an etch rate increase of more than four times of 1675 A/min was achieved at 65 degrees C. and with an H2O2 concentration of 9.79 M. The experimental results are graphically represented in FIG. 13.

While illustrative embodiments have been illustrated and described, various changes can be made therein without departing from the spirit and scope of the present disclosure.

1. A method of forming a metal feature, the method comprising:
(a) providing a microfeature workpiece that includes a substrate, a continuous titanium-containing barrier layer disposed on the substrate, a continuous first metal layer disposed on the barrier layer having a thickness, and a dielectric layer patterned on the first metal layer to provide a recess defining sidewall surfaces and a bottom surface, wherein the bottom surface of the recess is a metal surface and the sidewall surfaces of the recess are dielectric surfaces;
(b) depositing a second metal layer within the recess on an exposed top surface of the first metal layer;
(c) removing the dielectric layer to provide an exposed feature;
(d) etching a portion of the first metal layer using a first etching chemistry; and
(e) etching a portion of the barrier layer using a second etching chemistry to achieve a barrier layer undercut of less than or equal to 2 times the thickness of the barrier layer.

2. The method of claim 1, wherein the first metal layer is a seed layer.

3. The method of claim 1, further comprising electrochemically depositing a third metal layer within the recessed feature on an exposed top surface of the second metal layer.

4. The method of claim 3, further comprising electrochemically depositing a fourth metal layer within the recessed feature on an exposed top surface of the third metal layer.

5. The method of claim 1, wherein the second etching chemistry includes hydrogen peroxide and a fluoride ion.

6. The method of claim 1, wherein the second etching chemistry includes hydrogen peroxide and ammonium fluoride.

7. The method of claim 6, wherein the molarity of the hydrogen peroxide in the second etching chemistry is in the range of 0.300 M to 17.600 M.

8. The method of claim 6, wherein the molarity of the ammonium fluoride in the second etching chemistry is in the range of 0.012 M to 0.900 M.

9. The method of claim 6, wherein the molar ratio between hydrogen peroxide and ammonium fluoride is in the range of 83:1 to 13:1.

10. The method of claim 1, wherein the second etching chemistry further includes a caustic solution.

11. The method of claim 6, wherein the second etching chemistry further includes ammonium hydroxide.

12. The method of claim 1, wherein the temperature of the second etching chemistry is in the range of 35 degrees C. to 80 degrees C.

13. The method of claim 1, wherein the pH of the second etching chemistry is in the range of about 4.5 to about 8.0.

14. A method of forming a metal feature, the method comprising:
(a) providing a microfeature workpiece that includes a substrate, a continuous titanium-containing barrier layer disposed on the substrate, a continuous metal seed layer disposed on the barrier layer, and a dielectric layer patterned on the metal seed layer to provide a recess defining sidewall surfaces and a bottom surface, wherein the bottom surface of the recess is a metal surface and the sidewall surfaces of the recess are dielectric surfaces;
(b) electrochemically depositing a first metal layer within the recess on an exposed top surface of the metal seed layer;
(c) removing the dielectric layer to provide an exposed feature;
(d) etching a portion of the first metal layer using a first etching chemistry; and
(e) etching a portion of the barrier layer using a second etching chemistry including hydrogen peroxide and a fluoride ion.

15. A microfeature workpiece, comprising:
(a) a substrate;
(b) a microfeature disposed on the substrate, the microfeature including a titanium-containing barrier layer above the substrate, a metal seed layer above the barrier layer, and at least a first metallization layer disposed on the metal seed layer, wherein the barrier layer has an undercut of less than 2 times the thickness of the barrier layer.
